(19) United States
(12) Patent Application Publication
(10) Pub. No.: US 2009/0173944 A1
(43) Pub. Date: Jul. 9, 2009

(54) THIN FILM TRANSISTOR, ACTIVE DEVICE ARRAY SUBSTRATE AND LIQUID CRYSTAL DISPLAY PANEL

(75) Inventors: Po-Lin Chen, Hsinchu (TW); Ting Hsieh, Hsinchu (TW); Chun-Nan Lin, Hsinchu (TW); Wen-Ching Tsai, Hsinchu (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: Au Optronics Corporation, Hsinchu (TW)

(21) Appl. No.: 12/049,362

(22) Filed: Mar. 16, 2008

(30) Foreign Application Priority Data
Jan. 3, 2008 (TW) 97100188

(51) Int. Cl. H01L 33/00; H01L 29/786

(52) U.S. Cl. 257/66; 257/72; 257/E29.273; 257/E33.053

(57) ABSTRACT

A thin film transistor (TFT) includes a substrate, a gate, a gate dielectric layer, a channel layer, a source and a drain. The gate and the gate dielectric layer are disposed on the substrate and the gate dielectric layer covers the gate. The channel layer is disposed on the gate dielectric layer over the gate, and the source and the drain are respectively disposed on a portion of the channel layer at both sides of the gate. At least one of the gate, the source and the drain has a lower conductive layer, an upper conductive layer and an intermediate conductive layer located between the lower conductive layer and the upper conductive layer. The material of the lower conductive layer is different from the material of the intermediate conductive layer, and the thickness of the lower conductive layer is less than or equal to about 150 Å.

### CROSS-REFERENCE TO RELATED APPLICATION

This application claims the priority benefit of Taiwan application serial no. 97100188, filed on Jan. 3, 2008. The entirety the above-mentioned patent application is hereby incorporated by reference herein and made a part of specification.

### BACKGROUND OF THE INVENTION

1. Field of the Invention

The present invention generally relates to a semiconductor device structure, and more particularly, to a thin film transistor (TFT) structure.

2. Description of Related Art

In a semiconductor process, TFTs usually serve as a switching device. In general, a TFT includes a gate, a gate dielectric layer, a channel layer, a source and a drain, wherein the gate, source and the drain are respectively a single metal layer or a metal stacked layer composed of, for example, aluminum, chromium, tungsten, tantalum or titanium. In the above-mentioned conductive materials, aluminum has been broadly used in TFT electrode structures because of its low cost and unique properties thereof such as low resistivity, good adhesiveness onto a substrate and good etching characteristics easily to proceed an etching process, wherein the TFT electrodes include, for example, gate, source and drain.

However, aluminum has a large coefficient of thermal expansion (CTE), so that the thermal strain is easily produced between an aluminum layer and a substrate through heat treatment process, for example, annealing. Moreover, a mismatch of thermal strain between the aluminum layer and the substrate is created, wherein the aluminum layer suffers extreme stress during the annealing process and consequently the aluminum atoms in metallurgical structures diffuse along boundaries of aluminum crystal grains, which further leads to a formation of hillocks (or termed as aluminum hillocks). The hillocks may cause of current leakage, short-circuit, open-circuit or other faults affecting the TFT performance.

To solve the above-mentioned problem, one of the conventional solutions is to respectively form a molybdenum nitride layer on the aluminum layer and between the aluminum layer and the substrate so as to form a triple-layer structure of molybdenum nitride layer-aluminum layer-molybdenum nitride layer (MoN—Al—MoN), wherein the molybdenum nitride layers function to cover the boundaries of aluminum crystal grains to prevent the aluminum atoms from diffusing along the boundaries of aluminum crystal grains, and to lighten the above-mentioned mismatch of thermal strains because the molybdenum nitride layer has a CTE less than that of the aluminum layer. In this way, the prior art is able to avoid the formation of the hillocks.

In fact, during conducting a thin film deposition process of the molybdenum nitride layer by using, for example, reactive sputtering process, the process easily causes defects on the substrate surface. In more detail, when the reactive sputtering process uses molybdenum (Mo) as the target material and mixed gas of argon (Ar) and nitrogen (N) are taken as reaction gas, the Mo atoms sputtered through bombardment by ions would combine with the ionized N atoms, N ions or N atom free-radicals in plasma and form molybdenum nitride (MoN) deposited on the substrate. However, on the other hand, gas-phase nucleation often occurs in the chemical reactive environment during the thin film deposition process and the particles produced from the gas-phase nucleation are directly adsorbed or deposited onto the substrate surface and then form defects on the substrate surface. In addition, it is easily to cause micro arcing during the reactive sputtering process and the surface of the molybdenum target may bombarded through the micro arcing to produce a great deal of micro particles, wherein the micro particles also cause surface defects. In order to avoid the above-mentioned problem, the molybdenum nitride layer can be substituted by a molybdenum layer so as to form a triple structure of molybdenum layer-aluminum layer-molybdenum layer (Mo—Al—Mo triple-layer structure), wherein the method of forming a molybdenum layer can excluded the reactive sputtering process, thus, the above-mentioned problem can be significantly solved.

FIG. 1 is a diagram showing a conventional Mo—Al—Mo triple-layer structure with undercut phenomenon. Referring to FIG. 1, to form the electrode of a TFT with a Mo—Al—Mo triple-layer structure, first, a first molybdenum layer 102, an aluminum layer 104 and a second molybdenum layer 106 are sequentially formed on a substrate 100. Next, a patterned photoresist layer with an electrode pattern (not shown) is formed on the substrate 100. Next, a wet etching on the film layers 102, 104 and 106 is performed by using the patterned photoresist layer as a mask. Since the etching rate of the etching liquid on Mo is greater than that on Al, therefore, the etching liquid usually causes an undercut 110 on the first molybdenum layer 102, as shown in FIG. 1. When the electrode in the TFT adopts the Mo—Al—Mo triple-layer structure, the accompanied undercut makes the TFT fail to normally work. Moreover, when the above-mentioned structure is used in fabricating the wiring, for example, the scan lines or data lines connected to the TFT, the above-mentioned undercut may increase the impedance of the wiring, in some worse case, the undercut even makes the scan line or data line open-circuit, which largely affects the component performance of the TFT connected to the wiring.

### SUMMARY OF THE INVENTION

Accordingly, the present invention is directed to a TFT capable of avoiding formation of undercuts during the fabrication thereof.

The present invention is also directed to an active device array substrate, wherein the structure of the active device is capable of avoiding formation of undercuts during the fabrication process, and therefore the reliability of the pixels is effectively promoted.

The present invention is further directed to a liquid crystal display panel (LCD panel) capable of avoiding formation of the undercuts in the process and improving the display quality of the LCD panel.

The present invention provides a TFT, which includes a substrate, a gate, a gate dielectric layer, a channel layer, a source and a drain. The gate and the gate dielectric layer are disposed on the substrate, the gate dielectric layer covers the gate, the channel layer is disposed on the gate dielectric layer above the gate, and the source and the drain are respectively disposed on a part of the channel layer at both sides of the gate, wherein at least one of the gate, the source and the drain has a lower conductive layer, an upper conductive layer and an intermediate conductive layer located between the lower conductive layer and the upper conductive layer. The material of the lower conductive layer is different from that of the intermediate conductive layer, and the thickness of the lower conductive layer is less than or equal to about 150 Å (angstrom).

The present invention provides an active device array substrate, which includes a substrate, a plurality of scan lines, a plurality of data lines and a plurality of pixels. The scan lines and the data lines are disposed on the substrate, and the pixels are disposed on the substrate and electrically connected to the corresponding scan lines and data lines. Each of the pixels includes an active device and an electrode electrically connected to the active device, and at least one of the active devices includes a gate, a gate dielectric layer, a channel layer, a source and a drain. The gate and the gate dielectric layer are disposed on the substrate, the gate dielectric layer covers the gate, the channel layer is disposed on the gate dielectric layer above the gate and the source and the drain are respectively disposed on a part of the channel layer at both sides of the gate, wherein at least one of the gate, the source and the drain has a lower conductive layer, an upper conductive layer and an intermediate conductive layer located between the lower conductive layer and the upper conductive layer. The material of the lower conductive layer is different from that of the intermediate conductive layer, and the thickness of the lower conductive layer is less than or equal to about 150 Å.

The present invention provides an LCD panel, which includes an active device array substrate, an opposite substrate and a liquid crystal layer disposed therebetween. The active device array substrate includes a substrate, a plurality of scan lines, a plurality of data lines and a plurality of pixels. The scan lines and the data lines are disposed on the substrate, and the pixels are disposed on the substrate and electrically connected to the corresponding scan lines and data lines. Each of the pixels includes an active device and an electrode electrically connected to the active device, and at least one of the active devices includes a gate, a gate dielectric layer, a channel layer, a source and a drain. The gate and the gate dielectric layer are disposed on the substrate, the gate dielectric layer covers the gate, the channel layer is disposed on the gate dielectric layer above the gate and the source and the drain are respectively disposed on a part of the channel layer at both sides of the gate, wherein at least one of the gate, the source and the drain has a lower conductive layer, an upper conductive layer and an intermediate conductive layer located between the lower conductive layer and the upper conductive layer. The material of the lower conductive layer is different from that of the intermediate conductive layer, and the thickness of the lower conductive layer is less than or equal to about 150 Å. The opposite substrate is disposed at the opposite side of the active device array substrate, and the liquid crystal layer is disposed between the opposite substrate and the active device array substrate.

In an embodiment of the present invention, the TFT further includes an etching stop layer disposed over the channel layer.

In an embodiment of the present invention, the TFT further includes a heavily-doped semiconductor layer disposed between the channel layer and the source and between the channel layer and the drain.

In an embodiment of the present invention, the thickness of the above-mentioned lower conductive layer is about 100 Å.

In an embodiment of the present invention, the thickness of the intermediate conductive layer ranges from about 1200 Å to about 6000 Å.

In an embodiment of the present invention, the thickness of the upper conductive layer is ranges from about 100 Å to about 2000 Å.

In an embodiment of the present invention, the materials of the lower conductive layer and upper conductive layer include molybdenum (Mo), titanium (Ti), chromium (Cr), tungsten (W), tantalum (Ta), columbium (Nb), neodymium (Nd), a combination of the above-mentioned elements, an alloy of the above-mentioned elements or a nitride of the above-mentioned elements.

In an embodiment of the present invention, the material of the above-mentioned intermediate conductive layer includes aluminum (Al), copper (Cu), a combination of the above-mentioned metals or an alloy of aluminum-copper.

In an embodiment of the present invention, the active device further includes an etching stop layer disposed over the channel layer.

In an embodiment of the present invention, the active device further includes a heavily-doped semiconductor layer disposed between the channel layer and the source and between the channel layer and the drain.

In an embodiment of the present invention, the materials of the scan line and gate have a same composition, and the materials of the data line and the drain have a same composition.

In an embodiment of the present invention, the active device array substrate further includes at least a pad disposed on the substrate and the pad is electrically connected to the scan line or the data line, wherein the pad has a pad lower conductive layer, a pad upper conductive layer and a pad intermediate conductive layer. The pad intermediate conductive layer is located between the pad lower conductive layer and the pad upper conductive layer. The material of the pad lower conductive layer is different from the material of the pad intermediate conductive layer, and the thickness of the pad lower conductive layer is less than or equal to about 150 Å.

In an embodiment of the present invention, the opposite substrate includes a color filter substrate.

Since at least one of the gate, the source and the drain in the TFT of the present invention has a lower conductive layer, an intermediate conductive layer and an upper conductive layer, and the thickness of the lower conductive layer is less than or equal to about 150 Å, therefore, the structure of the present invention is able to avoid formation of undercut of the gate, the source or the drain, which may improve the reliability of the TFT and retain the desired electrical performance thereof and the normal operation of the pixel, so that the display quality of the LCD panel may be effectively promoted.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a diagram showing a conventional Mo—Al—Mo structure with the undercut phenomenon.

FIG. 2A is a cross-sectional diagram of a TFT according to the first embodiment of the present invention.

FIG. 2B is a cross-sectional diagram of another TFT according to the first embodiment of the present invention.

FIG. 2C is a cross-sectional diagram of yet another TFT according to the first embodiment of the present invention.

FIG. 2D is a cross-sectional diagram of yet another TFT according to the first embodiment of the present invention.

FIG. 3A is a top view diagram of an active device array substrate according to the second embodiment of the present invention.

FIG. 3B is a cross-sectional diagram along a line a-b of FIG. 3A.

FIG. 3C is a cross-sectional diagram along a line c-d of FIG. 3A.

FIG. 3D is a cross-sectional diagram along a line a-b of FIG. 3A including another type of active device.

FIG. 4 is a 3D-diagram of an LCD panel according to the third embodiment of the present invention.

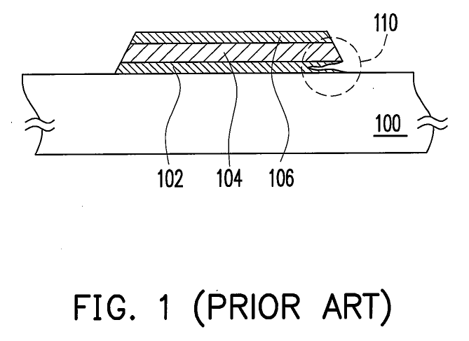

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### The First Embodiment

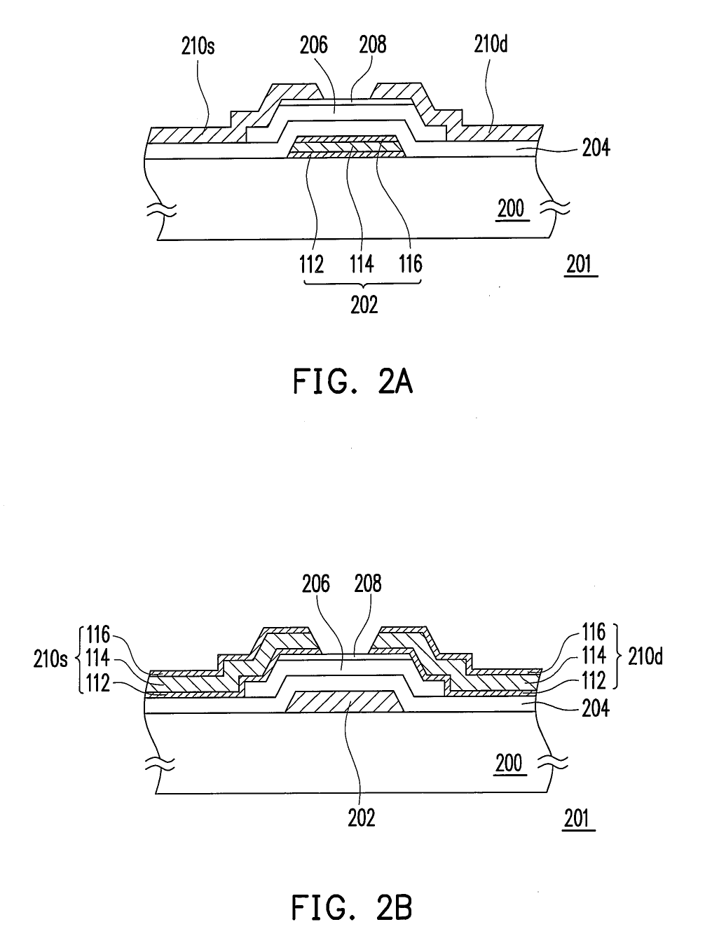

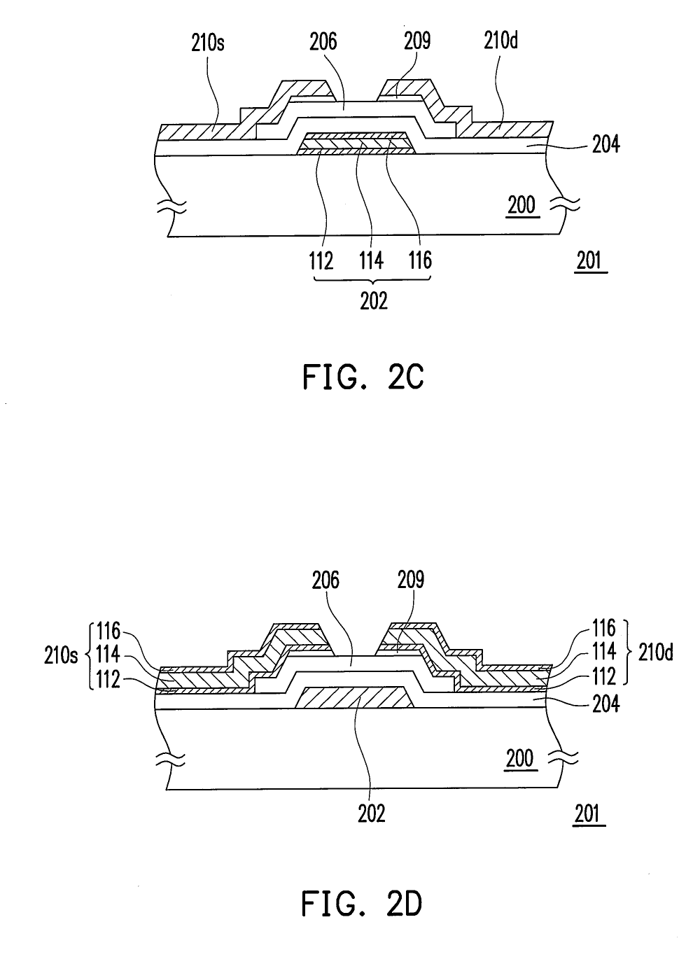

FIG. 2A is a cross-sectional diagram of a TFT according to the first embodiment of the present invention. Referring to FIG. 2A, a TFT 201 is disposed on a substrate 200 and the TFT includes a gate 202, a gate dielectric layer 204, a channel layer 206, a source 210s and a drain 210d, wherein the gate 202 and the gate dielectric layer 204 are disposed on the substrate 200, and the gate dielectric layer 204 covers the gate 202. The substrate 200 comprises, for example, a glass substrate, a quartz substrate or a substrate of any suitable material. The material of the gate dielectric layer 204 includes, for example, silicon oxide, silicon nitride or other dielectric materials. The channel layer 206 is disposed on the gate dielectric layer 204 over the gate 202, wherein the material of the channel layer 206 includes, for example, amorphous silicon (a-Si). The source 210s and the drain 210d are respectively disposed on a part of the channel layer 206 at both sides of the gate 202, wherein the source 210s and the drain 210d are respectively comprises, for example, a single-layer structure made of conductive material. In the present embodiment, the TFT 201 further includes an etching stop layer 208 disposed over the channel layer 206, wherein the etching stop layer 208 can be a single-layer structure or a multi-layer structure, and the material of the etching stop layer 208 include, for example but not limited to, silicon nitride or other materials.

Still referring to FIG. 2A, the gate 202 comprises a lower conductive layer 112, an intermediate conductive layer 114 and an upper conductive layer 116, wherein the intermediate conductive layer 114 is located between the lower conductive layer 112 and the upper conductive layer 116. In addition, the material of the lower conductive layer 112 is different from the material of the intermediate conductive layer 114, and the material of the lower conductive layer 112 can be the same or different from the material of the upper conductive layer 116. For example, the material of the intermediate conductive layer 114 includes, for example, aluminum (Al), copper (Cu), a combination of the above-mentioned metals or an alloy of aluminum-copper, and the thickness of the intermediate conductive layer 114 is in a range, for example, from about 1200 Å to about 6000 Å, and preferably from about 2400 Å to about 6000 Å. The material of the lower conductive layer 112 and the upper conductive layer 116 includes, for example, molybdenum (Mo), titanium (Ti), chromium (Cr), tungsten (W), tantalum (Ta), columbium (Nb), neodymium (Nd), a combination of the above-mentioned elements, an alloy of the above-mentioned elements or a nitride of the above-mentioned elements, and the thickness of the upper conductive layer 116 is in a range, for example, from about 100 Å to about 2000 Å. In the embodiment, the material of the intermediate conductive layer 114 comprises aluminium (Al), and the material of the lower conductive layer 112 and the upper conductive layer 116 comprises molybdenum (Mo). In other words, the gate 202 in the embodiment includes a Mo—Al—Mo multi-layer structure.

Note that the present invention can effectively overcome the undercut problem in the process caused by the prior art through controlling the thickness of the lower conductive layer 112. In more detail, the thickness of the lower conductive layer 112 can be controlled as required by the design, for example but not limited to less than or equal to about 150 Å, and preferably, for example, about 100 Å. In this way, the undercut formed in the fabrication process of the gate 202 can be avoided. For example, in the gate 202 of the embodiment, when the thickness of the lower conductive layer is controlled to be less than or equal to about 150 Å, the lower conductive layer contributes to protect the Mo—Al—Mo multi-layer structure from damage during the etching process. On the other hand, the lower conductive layer 112 and the upper conductive layer 116 of the present invention can serve as a buffer layer for the intermediate conductive layer 114 so as to effectively prevent the intermediate conductive layer 114 from damage in the subsequent process. Therefore, compared to the prior art, the present invention not only avoids the formation of hillocks on the aluminium layer but also avoids the formation of undercuts.

FIG. 2B is a cross-sectional diagram of another TFT according to the first embodiment of the present invention. Referring to FIG. 2B, a TFT 202 comprises a single-layer structure of conductive material, and a source 210s and a drain 210d respectively have a lower conductive layer 112, an intermediate conductive layer 114 and an upper conductive layer 116, wherein the thickness of the lower conductive layer 112 is less than or equal to about 150 Å. However in other embodiments, the gate, the source and the drain of a TFT may include a lower conductive layer with a thickness less than or equal to about 150 Å, an intermediate conductive layer and an upper conductive layer. Usually, the source and the drain are simultaneously formed; but in a TFT with some special requirements, only one of the source and the drain thereof has a lower conductive layer with a thickness less than or equal to about 150 Å, an intermediate conductive layer and an upper conductive layer. In other words, at least one of the gate, the source and the drain has a lower conductive layer with a thickness less than or equal to about 150 Å, an intermediate conductive layer and an upper conductive layer. The present invention does not limit the allocation of the triple structure, i.e. the structure composed of a lower conductive layer, an intermediate conductive layer and an upper conductive layer, in the TFT.

According to an embodiment of the present invention, the gate 202, the source 210s and the drain 210d respectively having a lower conductive layer with a thickness less than or equal to about 150 Å, an intermediate conductive layer and an upper conductive layer may be formed, for example, by the following process. First, a lower conductive material layer (not shown), an intermediate conductive material layer (not shown) and an upper conductive material layer (not shown) are sequentially formed on the substrate 200. Next, a patterned photoresist layer including the electrode pattern is formed on the upper conductive material layer above substrate 200. Next, using the patterned photoresist layer as a mask to perform a wet etching process on the triple conductive material layer to form an electrode. In general, when an electrode includes a conductive stacked layer composed of different materials, the etching rates of each conductive material layer is different, which tends to form undercuts at the electrode. However, it is possible to effectively overcome the formation of undercuts in the conductive stacked layer in a wet etching process by controlling the thickness of the lower conductive layer. Therefore, it is possible to effectively avoid the gate 202, the source 210s or the drain 210d from damage during the fabrication process and thereby retain the desired performance of the TFT 201.

FIG. 2C is a cross-sectional diagram of yet another TFT according to the first embodiment of the present invention. Referring to FIG. 2C, the TFT 201 herein is similar to the TFT 201 in FIG. 2A (where the same components are notated by the same marks) except that the TFT 201 in the embodiment includes a heavily-doped semiconductor layer 209 disposed between the channel layer 206 and the source 210s and between the channel layer 206 and the drain 210d. The method of forming the heavily-doped semiconductor layer 209 includes, for example, performing an ion implantation process with a high dopant concentration on a portion of the channel layer 206. Besides, the material of the heavily-doped semiconductor layer 209 includes, for example, N-type doped amorphous silicon (a-Si) or P-type a-Si. In addition, the TFT 201 in the embodiment does not include an etching stop layer.

FIG. 2D is a cross-sectional diagram of yet another TFT according to the first embodiment of the present invention. Referring to FIG. 2D, the TFT 201 herein is similar to the TFT 201 in FIG. 2B except that the TFT 201 in the embodiment includes a heavily-doped semiconductor layer 209 disposed between the channel layer 206 and the source 210s and between the channel layer 206 and the drain 210d. The material of the heavily-doped semiconductor layer 209 includes, for example, N-type doped amorphous silicon (a-Si) or P-type a-Si. In addition, the TFT 201 in the embodiment does not include an etching stop layer.

### The Second Embodiment

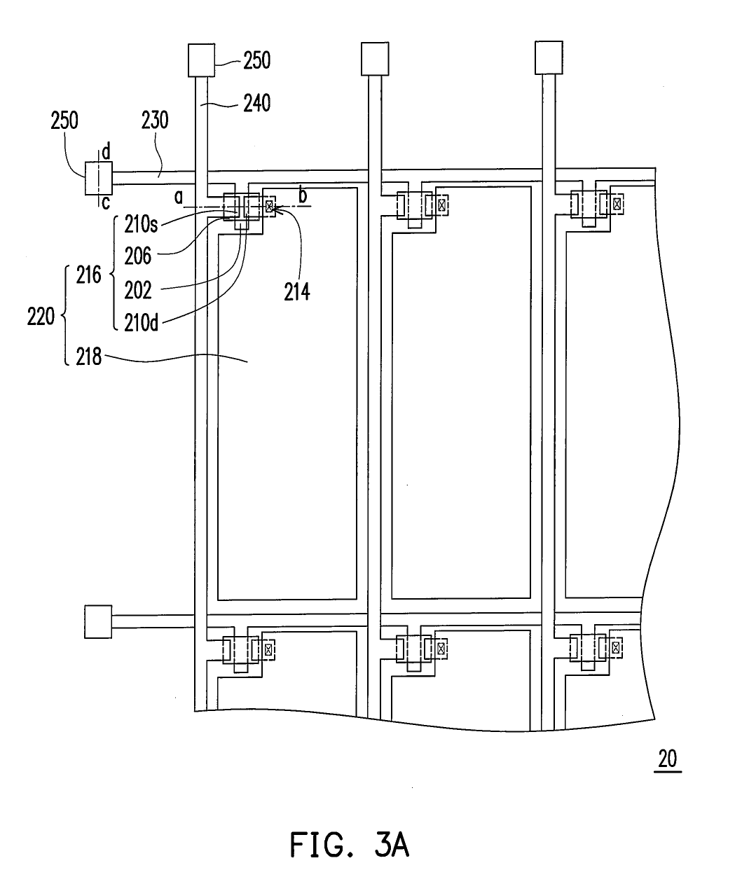

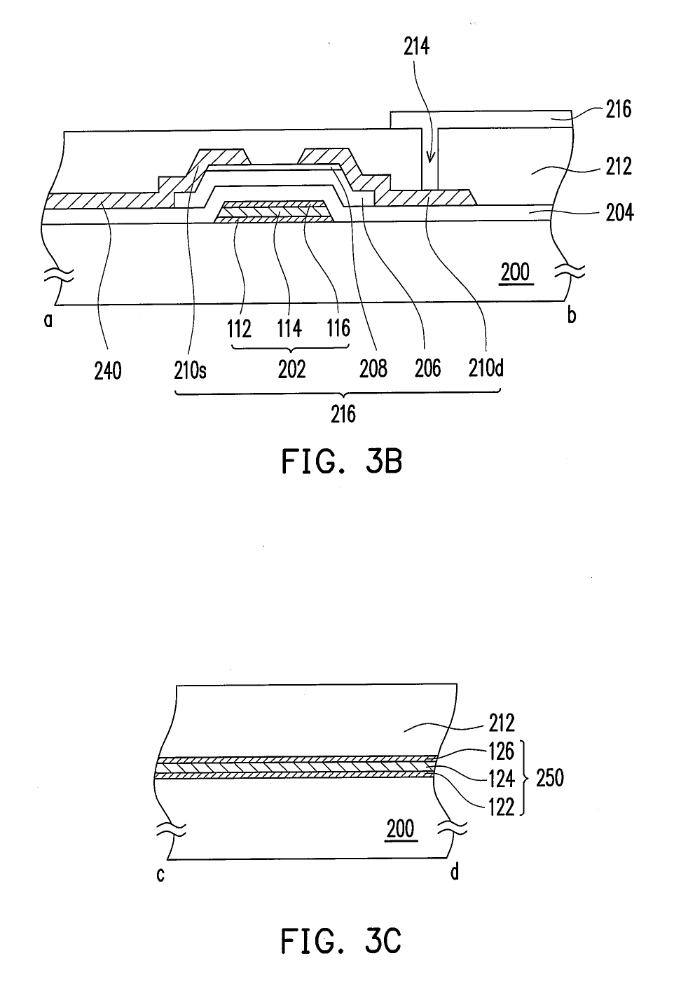

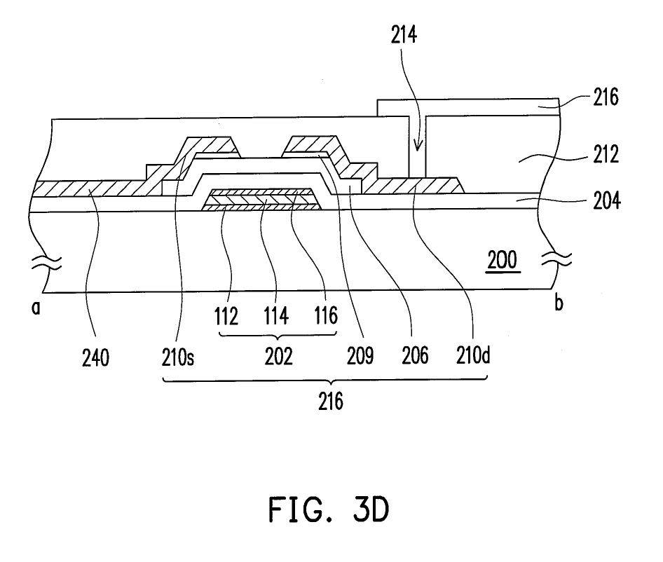

FIG. 3A is a top view diagram of an active device array substrate according to the second embodiment of the present invention, FIG. 3B is a cross-sectional diagram along a line a-b of FIG. 3A and FIG. 3C is a cross-sectional diagram along a line c-d of FIG. 3A. Referring to FIGS. 3A-3C, in an active device array substrate 20 of the present embodiment, only two pixels 220 are exemplarily shown. The active device array substrate 20 includes a substrate 200, a plurality of scan lines 230, a plurality of data lines 240 and a plurality of pixels 220, wherein the pixels 220 are respectively electrically connected to the corresponding scan line 230 and data line 240, and each pixel 220 includes an active device 216 and a pixel electrode 218 electrically connected to the active device 216. In the embodiment, the active device array substrate 20 further includes a plurality of pads 250 disposed on the substrate 200, wherein each pad 250 is respectively electrically connected to the a scan line 230 or a data line 240.

Referring to FIGS. 3A and 3B, at least one of the active devices 216 includes a gate 202, a gate dielectric layer 204, a channel layer 206, a source 210s and a drain 210d, wherein at least one of the gate 202, the gate dielectric layer 204, the channel layer 206, the source 210s and the drain 210d has a lower conductive layer 112, an upper conductive layer 116 and an intermediate conductive layer 114 located between the lower conductive layer 112 and the upper conductive layer 116. The material of the lower conductive layer 112 is different from the material of the intermediate conductive layer 114 and the thickness of the lower conductive layer is less than or equal to about 150 Å. In the embodiment as shown in FIG. 3B, the gate 202 comprises, for example but not limited to, a lower conductive layer 112 with a thickness ranging in a specific scope, an intermediate conductive layer 114 and an upper conductive layer 116. In addition, the arrangement of the gate 202, the gate dielectric layer 204, the channel layer 206, the etching stop layer 208, the source 210s and the drain 210d is the same as that in the first embodiment. Furthermore, the materials and thicknesses of the lower conductive layer 112, the intermediate conductive layer 114 and the upper conductive layer 116 are the same as those in the first embodiment, thus they are omitted to describe herein. Note that in other embodiments, instead of the gate, the source and the drain in an active device are allowed to have a lower conductive layer with a thickness ranging in a specific scope, an intermediate conductive layer and an upper conductive layer. Moreover, the above-mentioned active device can be disposed within a peripheral circuit region of an active device array substrate. The allocation of the active device 216 herein is an example, which the present invention does not limit thereto.

The gate 202 of the active device 216 is electrically connected to the corresponding scan line 230, and the source 210s is electrically connected to a data line 240. The active device 216 comprises, for example, a protection layer 212 to cover the gate dielectric layer 204, the channel layer 206, the source 210s and the drain 210d, and the pixel electrode 218 is disposed on the protection layer 212 and electrically connected to the drain 210d through a via hole 214. In the embodiment, the material of the scan line is substantially the same as that of the gate 202, and the material of the data line 240 is substantially the same as that of the source 210s and the drain 210d. In other words, the scan line 230 in the embodiment may have a lower conductive layer 112, an intermediate conductive layer 114 and an upper conductive layer 116 as well and the thickness of the lower conductive layer 112 is less than or equal to about 150 Å. In other embodiments where the source 210s and the drain 210d have the same structure, the data line 250 may have the same structure as that of the source and the drain.

In this way, in the embodiment where the scan line 230 or the data line 250 has a structure including a lower conductive layer 112 with a thickness ranging in a specific scope, an intermediate conductive layer 114 and an upper conductive layer 116, the structure of the present invention is able to effectively avoid the formation of the undercuts at the scan lines or the data lines by controlling the thickness of the lower conductive layer 112, which further avoids a possible open-circuit problem due to the formation of the undercuts during the patterning process on the scan line or the data line and ensure the desired operation of the pixels.

Referring to FIG. 3C, in an embodiment, the pad 250 comprises, for example, a pad lower conductive layer 122, a pad upper conductive layer 126 and a pad intermediate conductive layer 124 located between the pad lower conductive layer 122 and the pad upper conductive layer 126, wherein the material of the pad lower conductive layer 122 is different from the material of the pad intermediate conductive layer 124, and the thickness of the pad lower conductive layer 122 is less than or equal to about 150 Å. However the material and the thickness of the pad lower conductive layer 122 are, for example, the same as that of the lower conductive layer 112 and the materials of the thicknesses of the pad upper conductive layer 126 and the pad intermediate conductive layer 124 are, for example, respectively the same as that of the upper conductive layer 116 and the intermediate conductive layer 114. The above-mentioned triple-layer structure composed of a pad lower conductive layer, a pad intermediate conductive layer and a pad upper conductive layer may also be able to avoid formation of the undercuts at the pads 250 during the fabrication process.

FIG. 3D is a cross-sectional diagram along a line a-b of FIG. 3A including another type of active device. Referring to FIG. 3D, the active device 216 is similar to the active device 216 in FIG. 3B (where the same components are notated by the same marks) except that the active device 216 in the embodiment includes a heavily-doped semiconductor layer 209 disposed between the channel layer 206 and the source 210s and between the channel layer 206 and the drain 210d. The material of the heavily-doped semiconductor layer 209 includes, for example, N-type doped amorphous silicon (a-Si) or P-type a-Si. In addition, the active device 216 in the embodiment does not include an etching stop layer.

### The Third Embodiment

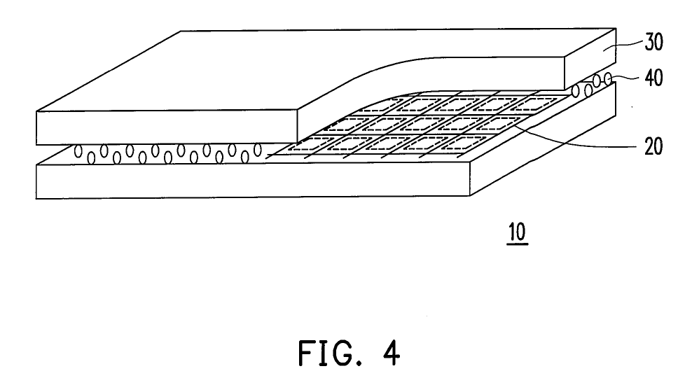

FIG. 4 is a 3D-diagram of an LCD panel according to the third embodiment of the present invention. Referring to FIG. 4, an LCD panel 10 includes an active device array substrate 20, which is the same as that in the above-mentioned embodiment, an opposite substrate 30 and a liquid crystal layer 40, wherein the opposite substrate 30 is disposed at a side opposite to the active device array substrate 20 and the liquid crystal layer 40 is disposed between the opposite substrate 30 and the active device array substrate 20. In the embodiment, the opposite substrate 30 includes, for example, a color filter substrate (CFS) and the LCD panel 10 can be transmissive display panel, transflective display panel, reflective display panel, color filter on array (COA), array on color filter (AOC) or any other types of substrate.

Since the gate, the source, the drain or a combination of the said gate, source and drain of at least an active device among a plurality of active devices in the LCD panel 10 has a lower conductive layer, an intermediate conductive layer and an upper conductive layer wherein the thickness of the lower conductive layer is less than or equal to about 150 Å, therefore, formation of undercuts during the fabrication of the active device would be unlikely. Moreover, it can avoid the scan line or the data line having the above-mentioned stacked layer structure from open-circuit problem due to formation of undercuts, which ensures the normal operation of the pixels and thereby promote the display quality of the LCD panel.

In summary, the gate, the source, the drain or a combination of the said gate, source and drain of the present invention comprises a lower conductive layer, an intermediate conductive layer and an upper conductive layer. By controlling the thickness of the lower conductive layer, the formation of the undercut during the etching process used for fabricating the electrode (for example, the gate, the source or the drain) may be avoided. Moreover, the opening circuit issue of the scan line and the data line due formation of the undercuts may be avoided, and therefore the desired performances of the TFT, and the desired operation of the pixels and the display quality of the LCD panel may be effectively promoted.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor, comprising:
a substrate;
a gate, disposed on the substrate;
a gate dielectric layer, disposed on the substrate to cover the gate;
a channel layer, disposed on the gate dielectric layer above the gate; and
a source and a drain, respectively disposed on a portion of the channel layer at both sides of the gate,
wherein at least one of the gate, the source and the drain comprises a lower conductive layer, an upper conductive layer and an intermediate conductive layer located between the lower conductive layer and the upper conductive layer, a material of the lower conductive layer is different from that of the intermediate conductive layer and a thickness of the lower conductive layer is less than or equal to about 150 Å.

2. The thin film transistor according to claim 1, wherein the thickness of the lower conductive layer is about 100 Å, the thickness of the intermediate conductive layer ranges from about 1200 Å to about 6000 Å, and the thickness of the upper conductive layer ranges from about 100 Å to about 2000 Å.

3. The thin film transistor according to claim 1, wherein the lower conductive layer and the upper conductive layer comprise molybdenum (Mo), titanium (Ti), chromium (Cr), tungsten (W), tantalum (Ta), columbium (Nb), neodymium (Nd), combinations thereof, an alloy thereof or a nitride thereof.

4. The thin film transistor according to claim 1, wherein the intermediate conductive layer comprises aluminum (Al), copper (Cu), combination thereof or an alloy thereof.

5. The thin film transistor according to claim 1, further comprising an etching stop layer disposed over the channel layer.

6. The thin film transistor according to claim 1, further comprising a heavily-doped semiconductor layer disposed between the channel layer and the source and between the channel layer and the drain.

7. An active device array substrate, comprising:
a substrate;
a plurality of scan lines and a plurality of data lines, disposed on the substrate; and
a plurality of pixels, disposed on the substrate and electrically connected to the corresponding scan lines and data lines, wherein each of the pixels comprises an active device and a pixel electrode electrically connected to the active device, and at least one of the active devices comprises:
a gate, disposed on the substrate;
a gate dielectric layer, disposed on the substrate to cover the gate;
a channel layer, disposed on the gate dielectric layer above the gate; and
a source and a drain, respectively disposed on a portion of the channel layer at both sides of the gate,
wherein at least one of the gate, the source and the drain has a lower conductive layer, an upper conductive layer and an intermediate conductive layer located between the lower conductive layer and the upper conductive layer, a material of the lower conductive layer is different from that of the intermediate conductive layer and the thickness of the lower conductive layer is less than or equal to about 150 Å.

8. The active device array substrate according to claim 7, wherein a thickness of the lower conductive layers is about 100 Å, the thickness of the intermediate conductive layer ranges from about 1200 Å to about 6000 Å, and the thickness of the upper conductive layer ranges from about 100 Å to about 2000 Å.

9. The active device array substrate according to claim 7, wherein the lower conductive layers and the upper conductive layers comprise molybdenum (Mo), titanium (Ti), chromium (Cr), tungsten (W), tantalum (Ta), columbium (Nb), neodymium (Nd), combinations thereof, an alloy thereof or a nitride thereof.

10. The active device array substrate according to claim 7, wherein each of the active devices further comprises an etching stop layer disposed over the channel layer.

11. The active device array substrate according to claim 7, wherein each of the active devices further comprises a heavily-doped semiconductor layer disposed between the channel layer and the source and between the channel layer and the drain.

12. The active device array substrate according to claim 7, wherein a composition of the scan lines and that of the gates are substantially the same, and a composition of the data lines and that of the sources and the drains are the substantially the same.

13. The active device array substrate according to claim 7, wherein the intermediate conductive layers comprise aluminum (Al), copper (Cu), combination thereof or an alloy thereof.

14. The active device array substrate according to claim 7, further comprising at least one pad disposed over the substrate and electrically connected to the scan lines or the data lines, wherein the pad comprises a pad lower conductive layer, a pad upper conductive layer and a pad intermediate conductive layer located between the pad lower conductive layer and the pad upper conductive layer, a material of the pad lower conductive layer is different from that of the pad intermediate conductive layer and a thickness of the pad lower conductive layer is less than or equal to about 150 Å.

15. A liquid crystal display panel, comprising:
an active device array substrate, comprising:
a substrate;
a plurality of scan lines and a plurality of data lines, disposed on the substrate; and
a plurality of pixels, disposed on the substrate and electrically connected to the corresponding scan lines and data lines, wherein each of the pixels comprises an active device and a pixel electrode electrically connected to the active device, and at least one of the active devices comprises:
a gate, disposed on the substrate;
a gate dielectric layer, disposed on the substrate to cover the gate;
a channel layer, disposed on the gate dielectric layer above the gate; and
a source and a drain, respectively disposed on a portion of the channel layer at both sides of the gate,
wherein at least one of the gate, the source and the drain comprises a lower conductive layer, an upper conductive layer and an intermediate conductive layer located between the lower conductive layer and the upper conductive layer, a material of the lower conductive layer is different from the material of the intermediate conductive layer and a thickness of the lower conductive layer is less than or equal to about 150 Å;
an opposite substrate, disposed at the side opposite to the active device array substrate; and
a liquid crystal layer, disposed between the opposite substrate and the active device array substrate.

16. The liquid crystal display panel according to claim 15, wherein the thickness of the lower conductive layers is about 100 Å, the thickness of the intermediate conductive layer ranges from about 1200 Å to about 6000 Å, and the thickness of the upper conductive layer ranges from about 100 Å to about 2000 Å.

17. The liquid crystal display panel according to claim 15, wherein the lower conductive layers and the upper conductive layers comprise molybdenum (Mo), titanium (Ti), chromium (Cr), tungsten (W), tantalum (Ta), columbium (Nb), neodymium (Nd), combinations thereof, an alloy thereof or a nitride thereof.

18. The liquid crystal display panel according to claim 15, wherein a composition of the scan lines and that of the gates are substantially the same, and a composition of the data lines and that of the sources and the drains are the substantially the same.

19. The liquid crystal display panel according to claim 15, wherein the intermediate conductive layers comprises aluminum (Al), copper (Cu), combination thereof or an alloy thereof.

20. The liquid crystal display panel according to claim 15, wherein the active device array substrate further comprises at least one pad disposed on the substrate and electrically connected to the scan lines or the data lines, wherein the pad comprises a pad lower conductive layer, a pad upper conductive layer and a pad intermediate conductive layer located between the pad lower conductive layer and the pad upper conductive layer, a material of the pad lower conductive layer is different from the material of the pad intermediate conductive layer and a thickness of the pad lower conductive layer is less than or equal to about 150 Å.
